(19) United States
(12) Patent Application Publication
(10) Pub. No.: US 2014/0174910 A1
(43) Pub. Date: Jun. 26, 2014

(54) Sputter Gun Shield

(71) Applicant: INTERMOLECULAR, INC., San Jose, CA (US)

(72) Inventor: Jay Dedontney, Prunedale, CA (US)

(73) Assignee: INTERMOLECULAR, INC., San Jose, CA (US)

(21) Appl. No.: 13/725,760

(22) Filed: Dec. 21, 2012

(51) Int. Cl. C23C 14/34

(52) U.S. Cl. CPC C23C 14/34
USPC 204/192.12; 204/298.11; 204/298.07; 204/192.1

(57) ABSTRACT

A shielding component and a sputter gun are described. The sputter gun has a housing. The housing has a region configured to expose a target surface. The shielding component extends around an inward facing periphery of the region. The shielding component comprises metal foam. The shielding component is configured to provide a fluid proximate to the target surface. An annular channel may be arranged to provide a gas through pores of the metal foam of the shielding component, to the region proximate to the target.

### BACKGROUND

Physical vapor deposition (PVD) is commonly used within the semiconductor industry, as well as within solar, glass coating, and other industries, for depositing thin films over a substrate. Sputter deposition is a physical vapor deposition (PVD) method of depositing thin films by sputtering, that is ejecting material from a source target by high-energy particle bombardment, which then deposits onto a substrate such as a silicon wafer.

A sputtered atom can leave the target surface in any available direction of free travel, and following Newton's laws of motion, will travel in a straight line until acted upon by another object or force. As sputtering typically takes place under high vacuum conditions, the mean free path for the sputtered atom can be rather “long”, hence the atoms tend to follow a line of sight trajectory from their originating location. When the sputtered atoms interact with any of the internally bounding surfaces of the apparatus, they can deposit, now leaving a material surface with electrical properties of the parent target material. In the case of a metal target, the sputtered atoms form a thin conducting layer on the surfaces visible from the originating location. As it may be desired to limit the available surfaces exposed to the sputtered atoms, shields may be implemented to intentionally restrict unhindered access to the interior of the apparatus by the sputtered atoms. The shields are used to limit the exposure of the sputtered atoms to the intended deposition region, or onto the limiting shields. As the shields accumulate more and more sputtered atoms, eventually randomly uniform thin films are created. As these thin films increase in thickness, the inherent internal stresses, compressive or tensile, can lead to structural failure of the thin film, where flaking or spalling of the films can occur. These large accumulations of atoms are considered particles, and can contaminate the surface where the intended deposition is occurring. Another failure mechanism that can occur is the buildup of sputtered atoms that can bridge small geometries within the apparatus creating changes in electrical operation of the tool. These could be seen as electrical shorts from energized surfaces to grounded surfaces due to a metal target being used, depositing electrically conductive materials on the surfaces inside the apparatus, or by covering energized surfaces with an insulating film if a target with non-conductive properties is being used. Shields are frequently removed, inspected, and cleaned or replaced as needed to prevent loss of workpiece material or productivity arising from these short comings. The removal, cleaning and inspection of the shields is time consuming and impacts throughput. Tool uptime and availability can be improved directly by extending the capacity to effectively “getter” these stray sputtered atoms, in turn delaying the onset of structural failure of the thin films leading to flaking and spalling of destructive contaminants.

Therefore, there is a need in the art for a solution which overcomes the drawbacks described above.

### SUMMARY

Sputter guns typically make use of at least one shield, to protect portions of the sputter gun from stray sputtered atoms. A metallic shield or shielding component disclosed herein comprises metal foam, and may allow an increase in mean time between cleanings or replacements of the metallic shield as a result of improved capacity to intercept stray atoms and extend the tool availability by extending the onset of spalling.

In some embodiments, a sputter gun includes a housing and a shielding component. The housing has a region configured to expose a target surface. The shielding component extends around an inward facing periphery of the region. That is, the shielding component is disposed around a perimeter of the target. The shielding component comprises metal foam and is configured to provide a fluid proximate to the target surface.

In some embodiments, a sputter gun includes an annular, metallic shield. The metallic shield provides a barrier to stray sputtering products from a target disposed proximate to the metallic shield. The metallic shield includes metal foam and an annular channel is disposed around an outer periphery of the metallic shield.

In some embodiments a method of operating a sputter gun is disclosed. The method includes flowing a gas through a metal foam portion of a metallic shield that at least partially surrounds a region proximate to a target of the sputter gun. A plasma is created from the gas in the region and sputtered atoms are deposited from the target onto a substrate.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1 illustrates a schematic diagram for implementing combinatorial processing and evaluation using primary, secondary, and tertiary screening.

FIG. 2 is a simplified schematic diagram illustrating a general methodology for combinatorial process sequence integration.

FIG. 3 is a simplified schematic diagram illustrating an integrated high productivity combinatorial (HPC) system.

FIG. 4 is a simplified schematic diagram illustrating a sputter chamber configured to perform combinatorial processing and full substrate processing.

FIG. 5 is a perspective cutaway view of a sputter gun, with a metallic shield in accordance with some embodiments.

FIG. 6 is a perspective cutaway close-up view of a portion of the sputter gun of FIG. 5, showing details of the metallic shield.

FIG. 7 is a perspective view of an example of metal foam, which can be used as a raw material in the manufacture of the metallic shield of FIGS. 5 and 6.

FIG. 8 is a flow diagram of a method of operating the sputter gun of FIGS. 5 and 6.

### DETAILED DESCRIPTION

The embodiments described herein provide a method and apparatus related to sputter deposition processing. It will be obvious, however, to one skilled in the art, that the present invention may be practiced without some or all of these specific details. In other instances, well known process operations have not been described in detail in order not to unnecessarily obscure the present invention.

Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in US patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

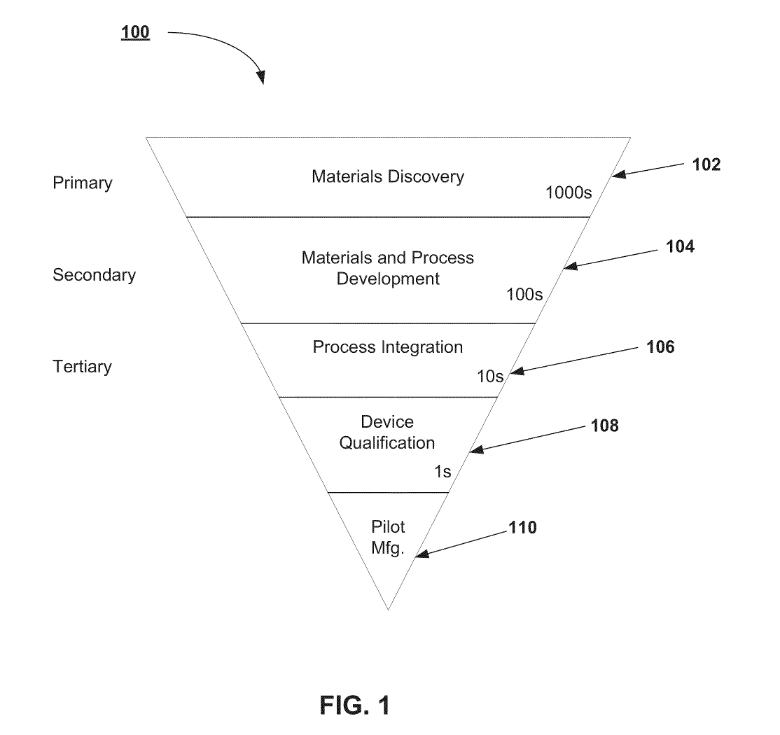

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

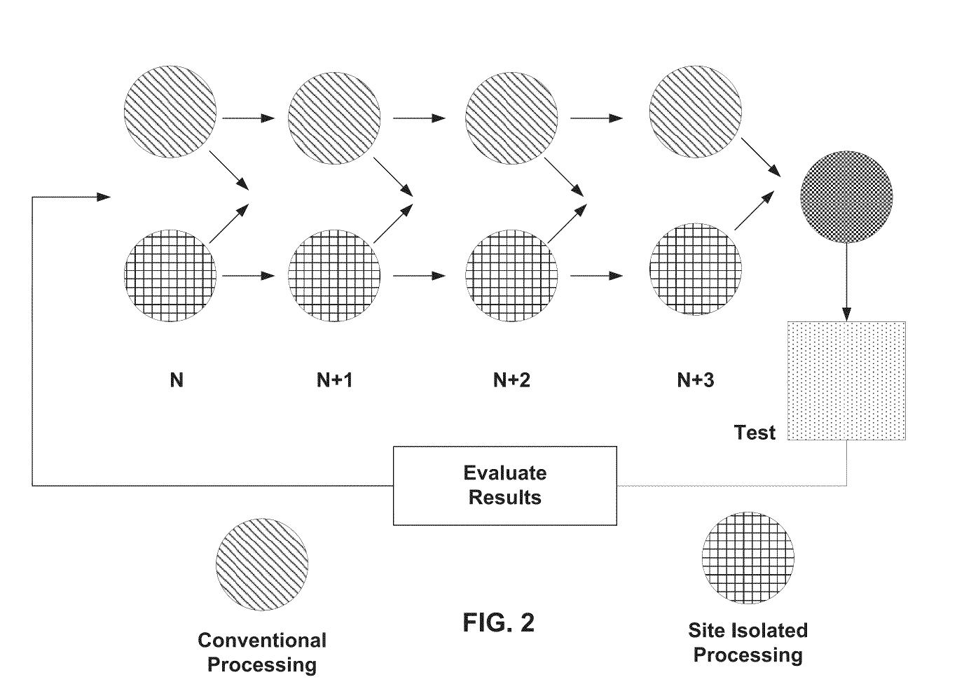

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

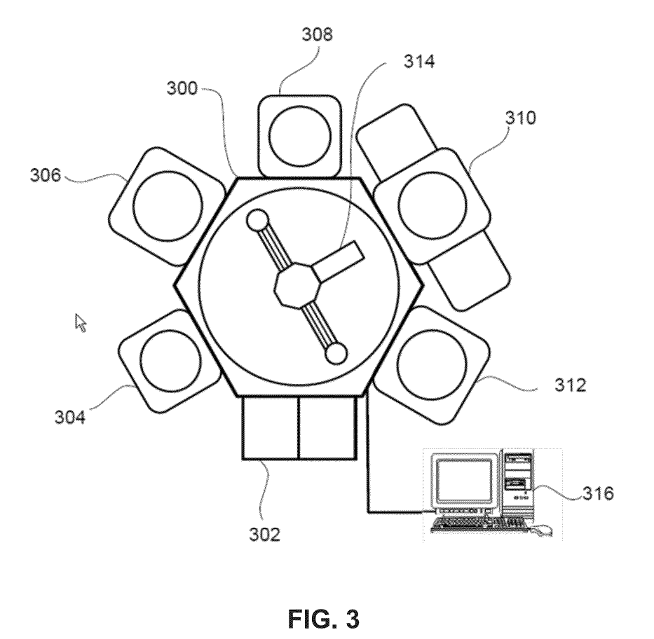

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. Nos. 11/672,478 and 11/672,473. With HPC system, a plurality of methods may be employed to deposit material upon a substrate employing combinatorial processes.

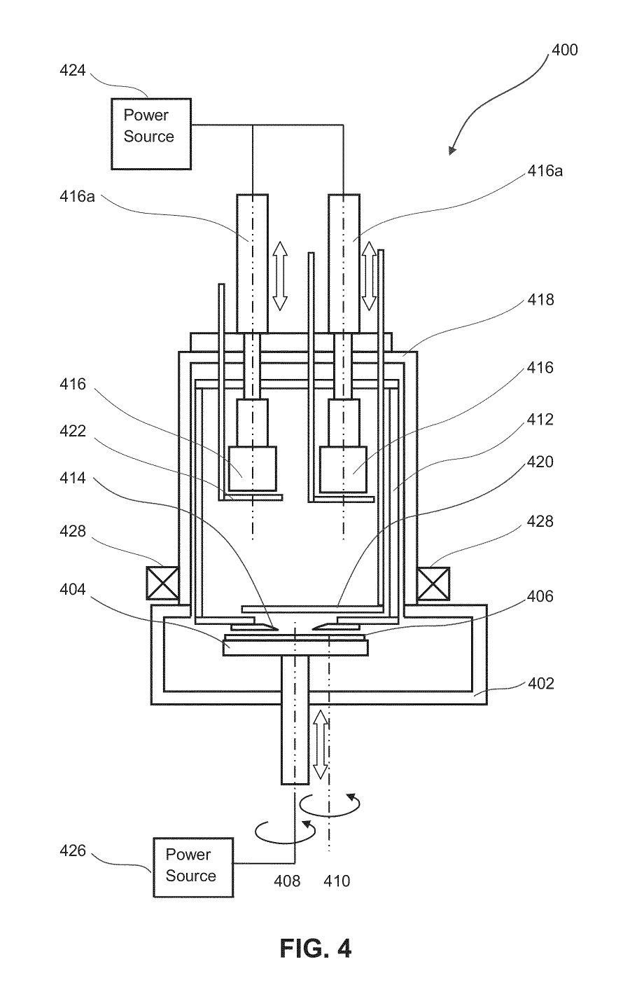

FIG. 4 is a simplified schematic diagram illustrating a sputter chamber configured to perform combinatorial processing and full substrate processing in accordance with some embodiments of the invention. Processing chamber 400 includes a bottom chamber portion 402 disposed under top chamber portion 418. Within bottom portion 402, substrate support 404 is configured to hold a substrate 406 disposed thereon and can be any known substrate support, including but not limited to a vacuum chuck, electrostatic chuck or other known mechanisms. Substrate support 404 is capable of both rotating around its own central axis 408 (referred to as “rotation” axis), and rotating around an exterior axis 410 (referred to as “revolution” axis). Such dual rotary substrate support is central to combinatorial processing using site-isolated mechanisms. Other substrate supports, such as an XY table, can also be used for site-isolated deposition. In addition, substrate support 404 may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source 426 provides a bias power to substrate support 404 and substrate 406, and produces a negative bias voltage on substrate 406. In some embodiments power source 426 provides a radio frequency (RF) power sufficient to take advantage of the high metal ionization to improve step coverage of vias and trenches of patterned wafers. In another embodiment, the RF power supplied by power source 426 is pulsed and synchronized with the pulsed power from power source 424.

Substrate 406 may be a conventional round 200 mm, 300 mm, or any other larger or smaller substrate/wafer size. In other embodiments, substrate 406 may be a square, rectangular, or other shaped substrate. One skilled in the art will appreciate that substrate 406 may be a blanket substrate, a coupon (e.g., partial wafer), or even a patterned substrate having predefined regions. In another embodiment, substrate 406 may have regions defined through the processing described herein. The term region is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

Top chamber portion 418 of chamber 400 in FIG. 4 includes process kit shield 412, which defines a confinement region over a radial portion of substrate 406. Process kit shield 412 is a sleeve having a base (optionally integrated with the shield) and an optional top within chamber 400 that may be used to confine a plasma generated therein. The generated plasma will dislodge atoms from a target and the sputtered atoms will deposit on an exposed surface of substrate 406 to combinatorial process regions of the substrate in some embodiments. In another embodiment, full wafer processing can be achieved by optimizing gun tilt angle and target-to-substrate spacing, and by using multiple process guns 416. Process kit shield 412 is capable of being moved in and out of chamber 400, i.e., the process kit shield is a replaceable insert. In another embodiment, process kit shield 412 remains in the chamber for both the full substrate and combinatorial processing. Process kit shield 412 includes an optional top portion, sidewalls and a base. In some embodiments, process kit shield 412 is configured in a cylindrical shape, however, the process kit shield may be any suitable shape and is not limited to a cylindrical shape.

The base of process kit shield 412 includes an aperture 414 through which a surface of substrate 406 is exposed for deposition or some other suitable semiconductor processing operations. Aperture shutter 420 which is moveably disposed over the base of process kit shield 412. Aperture shutter 420 may slide across a bottom surface of the base of process kit shield 412 in order to cover or expose aperture 414 in some embodiments. In another embodiment, aperture shutter 420 is controlled through an arm extension which moves the aperture shutter to expose or cover aperture 414. It should be noted that although a single aperture is illustrated, multiple apertures may be included. Each aperture may be associated with a dedicated aperture shutter or an aperture shutter can be configured to cover more than one aperture simultaneously or separately. Alternatively, aperture 414 may be a larger opening and plate 420 may extend with that opening to either completely cover the aperture or place one or more fixed apertures within that opening for processing the defined regions. The dual rotary substrate support 404 is central to the site-isolated mechanism, and allows any location of the substrate or wafer to be placed under the aperture 414. Hence, the site-isolated deposition is possible at any location on the wafer/substrate.

A gun shutter, 422 may be included. Gun shutter 422 functions to seal off a deposition gun when the deposition gun may not be used for the processing in some embodiments. For example, two process guns 416 are illustrated in FIG. 4. Process guns 416 are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. Gun shutter 422 can be transitioned to isolate the lifted process guns from the processing area defined within process kit shield 412. In this manner, the process guns are isolated from certain processes when desired. It should be appreciated that slide cover plate 422 may be integrated with the top of the process kit shield 412 to cover the opening as the process gun is lifted or individual cover plate 422 can be used for each target. In some embodiments, process guns 416 are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc.

Top chamber portion 418 of chamber 400 of FIG. 4 includes sidewalls and a top plate which house process kit shield 412. Arm extensions 416a, which are fixed to process guns 416 may be attached to a suitable drive, e.g., lead screw, worm gear, etc., configured to vertically move process guns 416 toward or away from a top plate of top chamber portion 418. Arm extensions 416a may be pivotally affixed to process guns 416 to enable the process guns to tilt relative to a vertical axis. In some embodiments, process guns 416 tilt toward aperture 414 when performing combinatorial processing and tilt toward a periphery of the substrate being processed when performing full substrate processing. It should be appreciated that process guns 416 may tilt away from aperture 414 when performing combinatorial processing in another embodiment. In yet another embodiment, arm extensions 416a are attached to a bellows that allows for the vertical movement and tilting of process guns 416. Arm extensions 416a enable movement with four degrees of freedom in some embodiments. Where process kit shield 412 is utilized, the aperture openings are configured to accommodate the tilting of the process guns. The amount of tilting of the process guns may be dependent on the process being performed in some embodiments.

Power source 424 provides power for sputter guns 416 whereas power source 426 provides RF bias power to an electrostatic chuck to bias the substrate when necessary. It should be appreciated that power source 424 may output a direct current (DC) power supply or a radio frequency (RF) power supply. Chamber 400 includes auxiliary magnet 428 disposed around an external periphery of the chamber. The auxiliary magnet 428 is located in a region defined between the bottom surface of sputter guns 416 and a top surface of substrate 406. Magnet 428 may be either a permanent magnet or an electromagnet. It should be appreciated that magnet 428 is utilized to provide more uniform bombardment of Argon ions and electrons to the substrate in some embodiments.

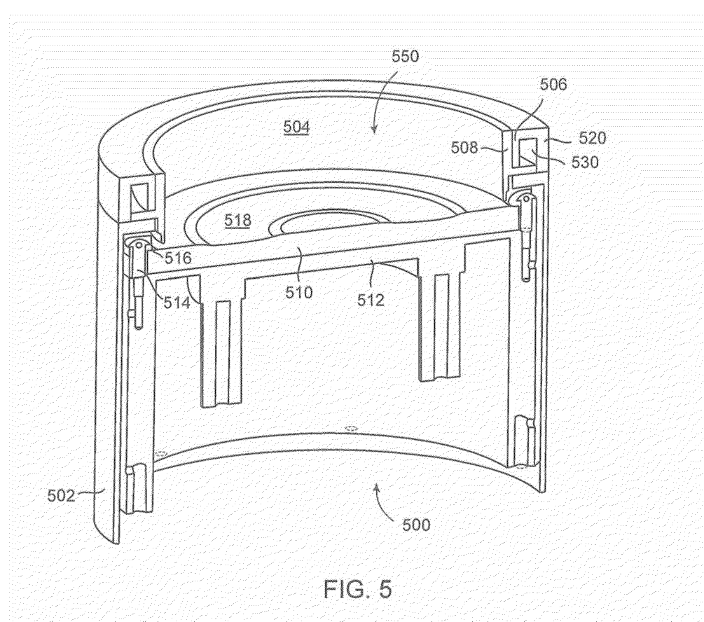

Embodiments of a sputter gun with a metallic shield in accordance with some embodiments are shown in FIGS. 5-8, and may be integrated with the combinatorial processing shown in FIGS. 1-4. However, this is not meant to be limiting as the sputter gun and shield described herein may be incorporated with conventional sputtering tools.

In a sputter gun, of a type that applies radiofrequency (RF) voltage or high-voltage direct current (DC) to bombard a sputtering target with ions from an excited plasma, a shield extending from the gun body is replaced by a shield made of metal foam in the embodiments described below. The shield extends circumferentially around a sputtering area into which a gas is admitted proximate to a target surface. The gas (e.g. argon) is excited into a plasma by the RF voltage or high-voltage DC, and provides ions that bombard the target surface. Sputtered atoms from the target are deposited onto a substrate within the chamber, and are also deposited onto the shield.

By forming the shield out of metal foam, adhesion of the sputtered atoms onto the shield is improved. The metal foam provides a larger and more textured surface area, with convoluted passageways, as compared to a shield made out of a solid metal (e.g. a cast and/or machined shield). Sputtered atoms adhering to the metal foam shield can then form a film of a much greater thickness, overall volume and mass, and with greater adhesion to the shield than is the case with a solid metal shield. The adhered sputtered film is much less likely to spall, i.e., detach in flakes and contaminate the substrate or electrically short a high-voltage surface of the sputter gun to a grounded surface of the gun body. Mean time to failure and mean time between cleanings or replacements of the metal shield are increased, as the shield can operate for a longer period of time before spalling occurs, thereby increasing the throughput.

In some embodiments, the gas is introduced to the sputtering chamber through the pores of the metal foam shield, from an annular channel or chamber proximate to an outer periphery of the metal foam shield. In these embodiments the metal foam acts as a diffuser of the gas. In some embodiments, a height of the metal foam shield extends outward or upward from a point adjacent to the front surface of the sputtering target. The metal foam shield includes an extension that functions as a base for an annular fluid channel extending around an outer periphery of the metal foam shield. In some embodiments, the metal foam shield is fabricated with metal foam having an open cell structure, which is then compressed in a die to final dimensions and porosity.

In some embodiments shown in FIG. 5, a sputter gun 500 has a housing 502 and a metallic shield 508. The housing 502 may also be referred to as a main gun shield, and the metallic shield 508 may be referred to as a shielding component, a metal shield or a metal foam shield. The metallic shield 508 is composed, at least partially, from metal foam in some embodiments. For example, embodiments of a metallic shield can be made of multiple components or subassemblies, at least one of which includes metal foam. In some embodiments, metallic shield 508 is composed entirely of metal foam. Metallic shield 508 surrounds a surface of target 510

Continuing with FIG. 5, a sputtering target 510 is attached within the housing 502 by a clamping ring 516 secured by target clamping ring screws 514. Atoms are ejected from a front surface 518 of the sputtering target 510 during a sputtering operation. Sputtering takes place when a gas is introduced to a region 550 proximate to the front surface 518 of target 510, and the gas is excited into a plasma. Ions from the plasma bombard the target 510, causing atoms to be ejected from the target 510. A water cooled backing plate 512 prevents the target 510 from overheating in some embodiments. A substrate opposing the front surface 518 of the target 510, receives sputtering atoms. The metallic shield 508 is composed of metal foam and extends around an inward facing periphery 504 of the region and at least partially surrounds the region 550 adjacent to the target 510. The metallic shield 508 provides a barrier to stray sputtering products from the target, and protects a portion of the sputter gun 500.

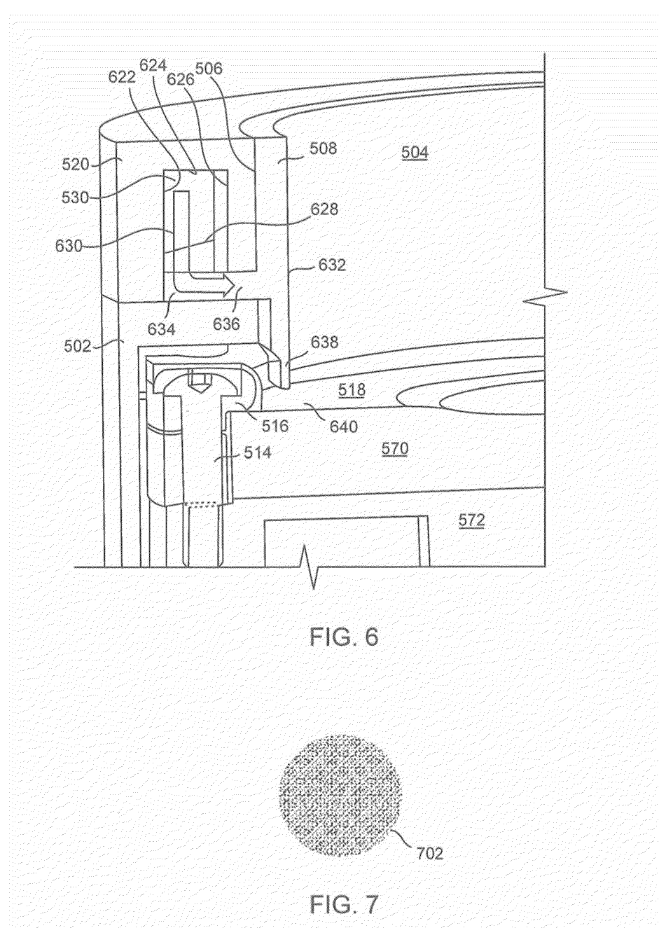

In some embodiments shown in FIGS. 5 and 6, the metallic shield 508 mates to or is otherwise affixed to a gas ring 520. Both the metallic shield 508 and the gas ring 520 are annular, i.e., ring or doughnut shaped. The gas ring 520 defines an annular fluid channel 530, extending around an outer periphery 506 of the metallic shield 508. In some embodiments, the housing 502 and the metallic shield 508 are grounded. In some embodiments, the gas ring 520 is made of metal and is conductive. It should be appreciated that grounding the metallic shield 508 results in the gas ring 520 being grounded, and the annular fluid channel 530 being grounded. It should be appreciated that sputter gun 500 may be integrated into the sputter chamber of FIG. 4 or a conventional sputter chamber where full substrate processing is performed as opposed to combinatorial processing.

FIG. 6 shows close-up details of the annular fluid channel 530. An extension 634 of the metallic shield 508 forms a base 628 of the annular fluid channel 530. Inner surfaces 622, 624, 626 of the gas ring 520 form walls of the annular channel 530. The extension 634 of the metallic shield 508 extends through a gap 636 between the gas ring 520 and the housing 502, thereby providing a pathway for gas to flow. The extension 634 of the metallic shield 508 is made of or includes metal foam of an open cell type, and is porous. In order to provide a gas for a plasma, a gas is introduced into the annular fluid channel 530. The gas moves along a gas flow path 630, from the annular fluid channel 530 through the metal foam pores of the extension 634 of the metallic shield 508, and through pores of the metallic shield 508 into the region 550 adjacent to front surface 518 of the target 510. It should be appreciated that the metal foam acts as a fine diffuser of the gas in some embodiments. Gas is distributed from an annular permeation region 632 of the metallic shield 508. The width of the annular permeation region 632 depends upon various geometries and dimensions and can be adjusted accordingly in some embodiments. Annular permeation region 632 may be contiguous along a circumference of the metallic shield 508 but this is not necessary as the annular permeation region may be non-contiguous depending on the application. Thus, the annular channel 530 is fluidly connected to the region adjacent to front surface 518 of the target 510, through the pores of the metal foam. With this arrangement, the shielding component is configured to provide a fluid proximate to the target surface, i.e., the front surface 518 of the sputtering target 510.

A gap 640 is maintained between a lower portion 638 of the metallic shield 508 and the front surface 518 of the target 510, so that a voltage potential expressed between the target 510 and the metallic shield 508 can excite the gas into a plasma. It should be appreciated that if this gap is bridged by deposited sputtering atoms or by flakes from spalling, a short results. Through the use of the metal foam in the metallic shield 508, the likelihood of spalling is decreased due to the increased available surface area for stray atoms to adhere. It should be appreciated that the mesh structure defined by the porous cells enhance the ability of the stray atoms to remain adhered to the surface as compared to a smoother surface or even surfaces slightly roughened.

An example of an open cell metal foam 702 is shown in FIG. 7. Aluminum is frequently used in making metal foam, however, alternative metals besides aluminum may be integrated with the embodiments described herein, such as any suitable conductive metal or conductive metal alloy. A characteristic of a metal foam is the porosity of the metal foam. For example, a metal foam may have 75-95% porosity, i.e., have 75-95% of the volume as void spaces. Density is expressed as a comparison to a solid metal having 100% density. For example, a metal foam with 80% porosity has 20% density of the solid metal. In some embodiments, the porosity of the metal foam for the metallic shield is between about 5% and 50%. In some embodiments, the porosity may be expressed in pores per inch and in some embodiments, the porosity of the metal foam for the metallic shield may be between about 10 and 100 pores per inch. It should be appreciated that these examples are not meant to be limiting as the porosity of the metal foam may vary depending on the application. It should be further appreciated that any electrically conductive porous media may be substituted for the metal foam in some embodiments.

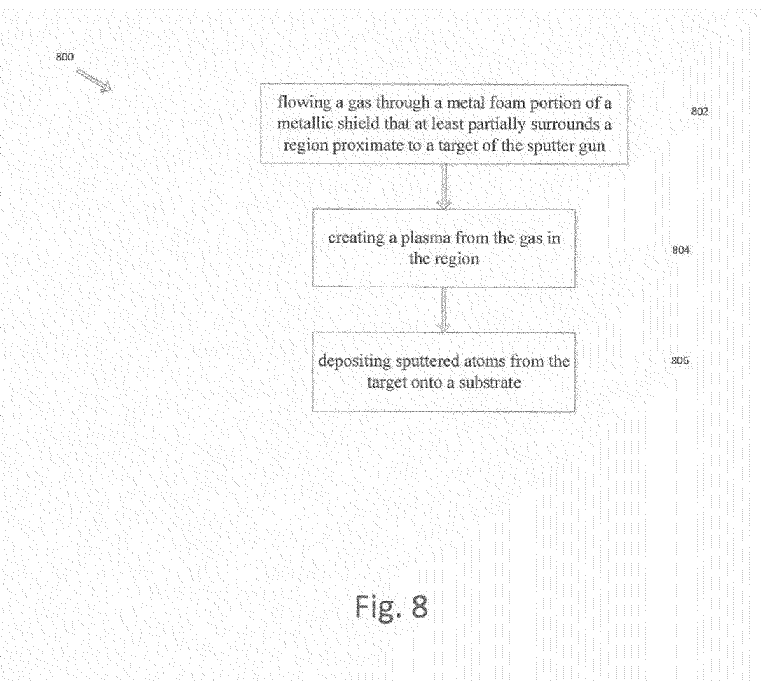

In FIG. 8, a method 800 of operating a sputter gun is shown. The method 800 can be practiced using embodiments of the sputter gun described above. In some embodiments of the method 800, the sputter gun has a metal shield that is composed of metal foam, as shown in FIGS. 5-7. The method initiates with operation 802 with flowing a gas through a metal foam portion of a metallic shield that at least partially surrounds a region proximate to a target of the sputter gun. As described above with reference to FIGS. 5 and 6, the metal foam may form a portion of the metallic shield or an entirety of the metallic shield. The method continues with operation 804 to produce a plasma from the gas in the region. In operation 806 sputtered atoms are deposited from the target onto a surface of a substrate opposing the surface of the target. It should be appreciated that through the embodiments described herein the mean time between cleaning or replacement of the metallic shield is increased, increasing the tool availability for processing, thereby improving overall throughput. In addition, the embodiments may be incorporated with combinatorial processing systems as well as conventional sputter processing systems.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

1. A sputter gun, comprising:
a housing, wherein the housing comprises:
a target attached to the interior of the housing by a clamping ring secured by target clamping ring screws; and
a shielding component,
wherein the shielding component is disposed around the perimeter of the target,
wherein the shielding component comprises metal foam.

2. The sputter gun of claim 1, further comprising:
an annular fluid channel extending around an outer periphery of the shielding component.

3. The sputter gun of claim 2, wherein the housing and the annular fluid channel are grounded.

4. The sputter gun of claim 2, wherein the shielding component functions as a portion of the containing boundary defining the annular fluid channel.

5. In a sputter gun, a shield comprising:
an annular, metallic shield that is operable to provide a barrier to sputtering products from a target disposed proximate to the metallic shield, the metallic shield comprising metal foam;
wherein the target is attached to the interior of the housing of the sputter gun by a clamping ring secured by target clamping ring screws; and
an annular channel disposed around an outer periphery of the metallic shield.

6. The shield of claim 5, wherein an extension of the metallic shield acts as a defining boundary to the annular channel.

7. The shield of claim 5, wherein the annular metallic shield and the annular channel are grounded.

8. The shield of claim 5, further comprising:
a gas ring mated to the metallic shield and having inner surfaces defining walls of the annular channel;
wherein a base of the annular channel is defined by a portion of the metallic shield.

9. The shield of claim 8, wherein:
the gas ring is arranged to provide a gas through the base of the annular channel to a region proximate to the target.

10. The shield of claim 5, wherein:
the annular channel is arranged to provide a gas through pores of the metal foam of the metallic shield, to a region proximate to the target.

11. The shield of claim 10, wherein:
the metal foam acts as a diffuser of the gas.

12. The shield of claim 5, wherein:
the annular channel is fluidly connected to a region adjacent to the target, by pores of the metal foam.

13. (canceled)

14. A method of operating a sputter gun, comprising:
flowing a gas through a metal foam portion of a metallic shield disposed around a perimeter of a target of the sputter gun;
creating a plasma from the gas; and
depositing sputtered atoms from the target onto a substrate.

15. The method of claim 14, further comprising:
grounding the metallic shield; and
applying one of a radiofrequency voltage or high-voltage DC to the target.

16. The method of claim 14, wherein the metal foam comprises a conductive metal or conductive metal alloy.

17. The method of claim 14, further comprising:
flowing the gas to the region from an annular channel proximate to an outer periphery of the metallic shield.

18. The method of claim 17, wherein the metal foam portion comprises a base of the annular channel.

19. The method of claim 14, wherein the metal foam completely surrounds an outer periphery of the region.

20. The method of claim 14, wherein the metal foam comprises aluminum.
